(19) United States
(12) Patent Application Publication
(10) Pub. No.: US 2007/0291146 A1
(43) Pub. Date: Dec. 20, 2007

(54) Semiconductor Chip

(75) Inventor: Josuke Sakiyama, Kyoto (JP)

Correspondence Address: FISH & RICHARDSON P.C., P.O. BOX 1022, MINNEAPOLIS, MN, 55440-1022, US

(73) Assignee: ROHM CO., LTD., Kyoto (JP)

(21) Appl. No.: 11/718,552

(22) PCT Filed: Nov. 1, 2005
(86) PCT No.: PCT/JP05/20116

§ 371 Date: May 3, 2007

(30) Foreign Application Priority Data
Nov. 5, 2004 (JP) 2004-322191

(51) Int. Cl. H04N 3/15

(52) U.S. Cl. 348/294; 348/E03.017

(57) ABSTRACT

A semiconductor chip provided with a light-sensitive device portion having a plurality of light-sensitive devices arranged linearly in the longer side direction, and a read-out circuit cell portion having read-out circuit cells arranged linearly in the longer side direction, each corresponding to one light-sensitive device, has a common signal line for a signal output and a common signal line for a reference output, that are a pair of signal lines, formed in a conductor portion lying between the read-out circuit cell portion and a logic circuit portion in such a way that they extend in the longer side direction while exchanging their positions in the shorter side direction every predetermined length.

### TECHNICAL FIELD

The present invention relates to a semiconductor chip that is suitable for an image sensor having a light-sensitive device such as a photo diode and a circuit for processing a signal therefrom, which are integrated on the same semiconductor substrate.

### BACKGROUND ART

Conventionally, a semiconductor chip used as an image sensor that reads out an image is used in electronic appliances such as facsimiles. This semiconductor chip has, as disclosed in Patent Publication 1, for example, light-sensitive devices arranged linearly, each corresponding to one pixel, and therefore has the shape of an elongate rectangle.

FIG. 3A is a plan view showing the whole of such a conventional semiconductor chip 101, FIG. 3B is a plan view showing an enlarged end portion thereof, and FIG. 3C is a plan view of a pair of signal lines, showing a partially enlarged view of FIG. 3B. As shown in FIG. 3A, this semiconductor chip 101 has the shape of an elongate rectangle. FIG. 3B is an enlarged view of an end portion of FIG. 3A, showing: a light-sensitive device portion 102 having light-sensitive devices 120, each corresponding to one pixel, arranged linearly from one shorter side to the other; a read-out circuit cell portion 103 having read-out circuit cells 130 arranged linearly, each corresponding to one light-sensitive device 120; a conductor portion 104 having a common signal line LD for a signal output and a common signal line DD for a reference output formed therein, which are a pair of signal lines shown in FIG. 3C; a logic circuit portion 105 that receives an external clock and a start signal, and generates a control signal for controlling the read-out circuit cell portion 103 and an analog circuit portion 106, which will be described below; and the analog circuit portion 106 including a subtraction circuit and an amplification circuit that output a voltage corresponding to the difference in voltage between the common signal line LD for a signal output and the common signal line DD for a reference output. The analog circuit portion 106 has a plurality of input/output pads 107 formed therein.

Here, the common signal line LD for a signal output and the common signal line DD for a reference output are formed along almost the entire length of the longer side of the conductor portion 104, that is, in FIG. 3A, they are formed in parallel to each other from the vicinity of the left end thereof to the vicinity of the right end thereof. The problem here is that the common signal line LD for a signal output and the common signal line DD for a reference output thus formed are so long that noise is easily superimposed thereon. However, by causing them to be located in the same position as possible and making them as alike as possible, the waveforms of noise superimposed thereon, if any, are made substantially the same, and thereby much of the noise is eliminated by the following subtraction circuit.

Patent document 1: JP-A-H09-205518

### DISCLOSURE OF THE INVENTION

Problems to be Solved by the Invention

In recent years, as electronic appliances such as facsimiles have become more and more compact, smaller printed circuit boards on which semiconductor chips used as image sensors are mounted have been increasingly sought after, and accordingly there has been a demand for size reduction in the semiconductor chips in the shorter side direction. Moreover, as the number of pixels has increased, the frequency of an external clock that serves as a reference for a control signal has increased.

Therefore, with a view to developing a semiconductor chip used as an image sensor that can realize a size reduction in the shorter side direction, the inventor of the present invention has made shorter the distance between the common signal lines for a signal output and for a reference output and the logic circuit portion, only to find out that switching noise from the logic circuit portion that cannot be eliminated by the subtraction circuit is superimposed thereon, leaving a large noise waveform in an output signal outputted to the outside.

In view of the conventionally experienced problems described above, it is an object of the present invention to provide an elongate rectangular semiconductor chip in which the layout of a pair of signal lines with a large total length is so designed as to permit easy elimination of noise superimposed thereon.

Means for Solving the Problem

To achieve the above object, according to the present invention, in a semiconductor chip having the shape of an elongate rectangle and having a logic circuit portion where switching noise occurs and a conductor portion having a pair of signal lines formed therein, the pair of signal lines each have a near segment located closer to a practical outer edge of the logic circuit portion extending in the longer side direction of the logic circuit portion, a far segment located farther therefrom, and a connecting segment connecting therebetween, and the pair of signal lines are disposed in such a way that a near segment of one of the pair of signal lines is parallel to a far segment of the other, and a connecting segment of one of the pair of signal lines and a connecting segment of the other cross each other.

With this configuration, the pair of signal lines are disposed in such a way that they alternately and repeatedly come closer to and go farther away from the logic circuit portion where noise tends to occur.

Preferably, according to the present invention, the semiconductor chip may be further provided with a light-sensitive portion in which a plurality of light-sensitive devices, each corresponding to one pixel, are arranged linearly in the longer side direction, and a read-out circuit cell portion in which a plurality of read-out circuit cells, each corresponding to one light-sensitive device, are arranged linearly in the longer side direction. The logic circuit portion may generate a control signal for controlling the read-out circuit cell portion. The pair of signal lines may be composed of a common signal line for a signal output of the plurality of light-sensitive devices and a common signal line for a reference output of the plurality of light-sensitive devices, and may be formed between the read-out circuit cell portion and the logic circuit portion.

With this configuration, the common signal line for a signal output of the light-sensitive devices and the common signal line for a reference output of the light-sensitive devices are disposed in such a way that they alternately and repeatedly come closer to and go farther away from the logic circuit portion where output noise tends to occur.

Advantages of the Invention

According to the present invention, in a semiconductor chip, a pair of signal lines each have a near segment located closer to a practical outer edge extending in the longer side direction of a logic circuit portion, a far segment located farther therefrom, and a connecting segment connecting therebetween, and the pair of signal lines are disposed in such a way that a near segment of one of the pair of signal lines is parallel to a far segment of the other, and a connecting segment of one of the pair of signal lines and a connecting segment of the other cross each other. This makes it possible to easily eliminate noise from the pair of signal lines, despite their large total length, because the noise waveforms superimposed thereon are substantially the same.

Advisably, according to the present invention, in the semiconductor chip, the noise waveforms superimposed on a common signal line for a signal output of light-sensitive devices and on a common signal line for a reference output of the light-sensitive devices are substantially the same. This makes it possible to easily eliminate the noise by causing a subtraction circuit in the following stage to perform subtraction of two signals on these common signal lines.

### BRIEF DESCRIPTION OF DRAWINGS

FIG. 1 A circuit diagram showing the semiconductor chip used as an image sensor;

FIG. 2A A plan view showing the whole of the semiconductor chip of an embodiment of the present invention;

FIG. 2B A plan view showing an enlarged end portion of the semiconductor chip;

FIG. 2C A plan view of a pair of signal lines, showing a partially enlarged view of the semiconductor chip;

FIG. 3A A plan view showing the whole of a conventional semiconductor chip;

FIG. 3B A plan view showing an enlarged end portion of the conventional semiconductor chip; and

FIG. 3C A plan view of a pair of signal lines, showing a partially enlarged view of the conventional semiconductor chip.

List of Reference Symbols

| | |
|---|---|
| 1, 101 | semiconductor chip |
| 2, 102 | light-sensitive device portion |
| 3, 103 | circuit cell portion |
| 4, 104 | conductor portion |
| 5, 105 | logic circuit portion |
| 6, 106 | analog circuit portion |
| 7, 107 | input/output pad |
| 20, 120 | light-sensitive device |
| 30, 130 | circuit cell |
| 31, 35, 36, 37, 66 | transistor |
| 32, 61, 62, 65 | buffer |
| 33, 34 | capacitor |
| 41, 47 | far segment |
| 42, 44, 46, 48 | connecting segment |
| 43, 45 | near segment |
| 63 | subtraction circuit |
| 64 | amplification circuit |
| 71 | input pad |
| 73 | output pad |

### BEST MODE FOR CARRYING OUT THE INVENTION

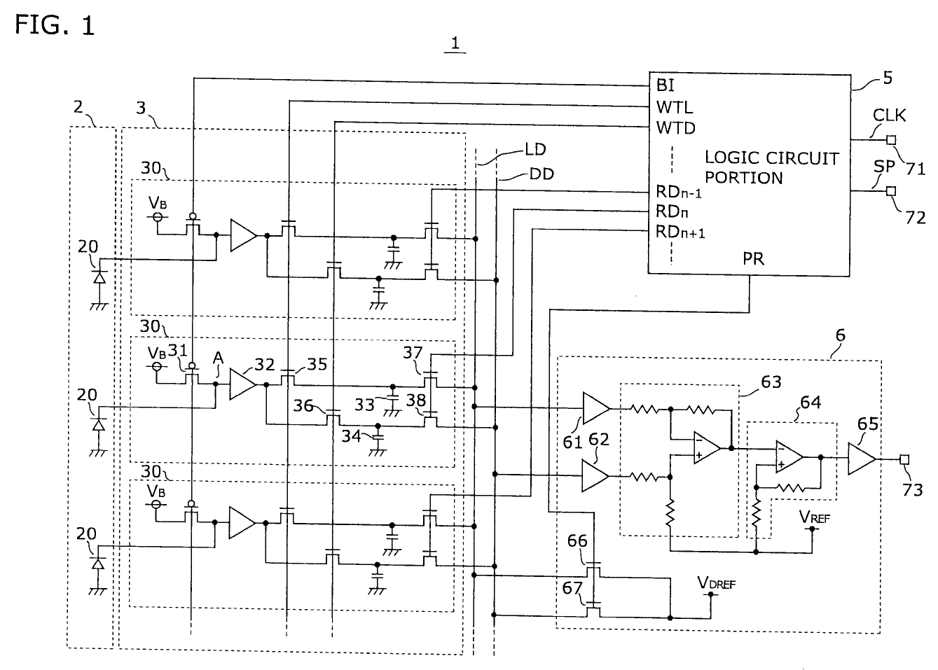

Hereinafter, an embodiment of the present invention will be described with reference to the accompanying drawings. First, the circuit of a semiconductor chip used as an image sensor will be described. FIG. 1 is a circuit diagram of a semiconductor chip 1. The semiconductor chip 1 is composed of a light-sensitive device portion 2 having a plurality of light-sensitive devices 20, a read-out circuit cell portion 3 having read-out circuit cells 30, each corresponding to one light-sensitive device 20, a logic circuit portion 5 that generates various control signals, and an analog circuit portion 6 that performs amplification or the like and outputs an output signal to the outside via an output pad 73. The logic circuit portion 5 receives an external clock CLK and a start signal SP via input pads 71 and 72, respectively, and generates control signals BI, WTL, WTD, RDₙ₋₁, RDₙ, and RDₙ₊₁ for controlling the read-out circuit cell portion 3, and a control signal PR for controlling the analog circuit portion 6, which will be described below. The control signals BI, WTL, and WTD are commonly used in all the read-out circuit cells 30. On the other hand, the control signals RDₙ₋₁, RDₙ, and RDₙ₊₁ are used individually by the read-out circuit cells 30, and the number thereof corresponds to the number of read-out circuit cells 30.

The read-out circuit cell 30 located at the center of the figure will be described in detail. The read-out circuit cell 30 is composed of a PMOS transistor 31 that precharges a connection point A connected to the light-sensitive device 20 to a bias voltage V_{B} according to the control signal BI, a buffer 32 that buffers and outputs the voltage of the connection point A, capacitors 33 and 34 that temporarily store the output voltage of the buffer 32, NMOS transistors 35 and 36 that transmit the output voltage of the buffer 32 to the capacitors 33 and 34 according to the control signals WTL and WTD, respectively, and NMOS transistors 37 and 38 that transmit the voltages of the capacitors 33 and 34, respectively, to a common signal line LD for a signal output and a common signal line DD for a reference output, which are a pair of signal lines, according to the control signal RDₙ. The configuration of the read-out circuit cells 30 located in the upper and lower parts of the figure is the same as that of the read-out circuit cell 30 located at the center thereof. Note that the buffer 32 consists of an emitter follower circuit or the like.

The analog circuit portion 6 is composed of buffers 61 and 62 that respectively buffer and output the voltages of the common signal line LD for a signal output and the common signal line DD for a reference output, a subtraction circuit 63 that outputs a voltage corresponding to the difference between the output voltage of the buffer 61 and the output voltage of the buffer 62, an amplification circuit 64 that amplifies the output voltage of the subtraction circuit 63 and then outputs it, and a buffer 65 that buffers the output voltage of the amplification circuit 64 and then outputs it to the outside. Moreover, the analog circuit portion 6 has NMOS transistors 66 and 67 that respectively precharge the common signal line LD for a signal output and the common signal line DD for a reference output to a reference voltage V_{DREF} for common signal lines according to the control signal PR.

The semiconductor chip 1 used as an image sensor operates as follows. The connection point A has a voltage corresponding to the amount of light incident on the light-sensitive device 20. When the semiconductor chip 1 is activated by a start signal SP, the voltage of the connection point A is stored in the capacitor 33 via the buffer 32 and the transistor 35, followed by a precharge of the connection point A via the transistor 31. Then, the voltage of the connection point A is stored in the capacitor 34 via the buffer 32 and the transistor 36 with no light incident on the light-sensitive device 20. Then, after the common signal line LD for a signal output and the common signal line DD for a reference output are precharged via the transistors 66 and 67, respectively, the transistors 37 and 38 of each read-out circuit cell 30 are sequentially turned on, transmitting the voltage of the capacitor 33 to the common signal line LD for a signal output and transmitting the voltage of the capacitor 34 to the common signal line DD for a reference output. The voltages of the common signal line LD for a signal output and the common signal line DD for a reference output are inputted via the buffers 61 and 62, respectively, to the subtraction circuit 63, and the output voltage therefrom is amplified by the amplification circuit 64 and then outputted to the outside via the buffer 65. Here, the subtraction circuit 63 outputs the difference between the voltages of the common signal line LD for a signal output and the common signal line DD for a reference output, and thereby eliminates the same noise waveform components superimposed on those voltages.

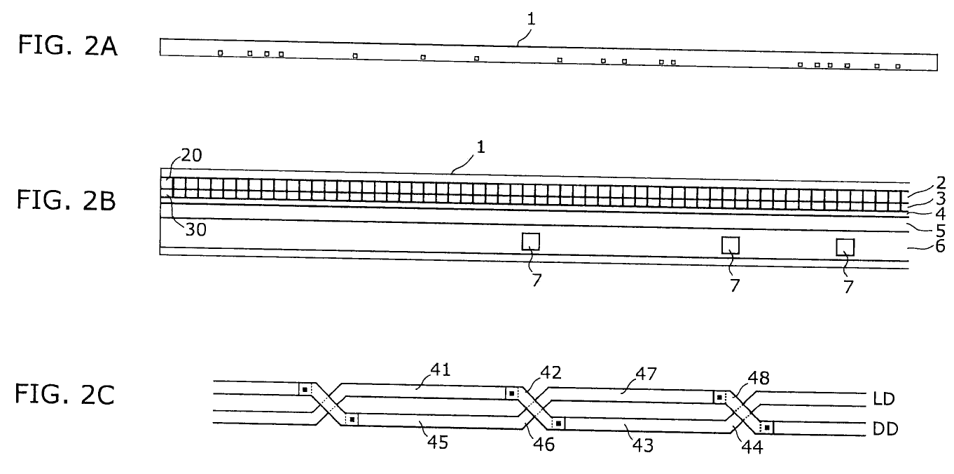

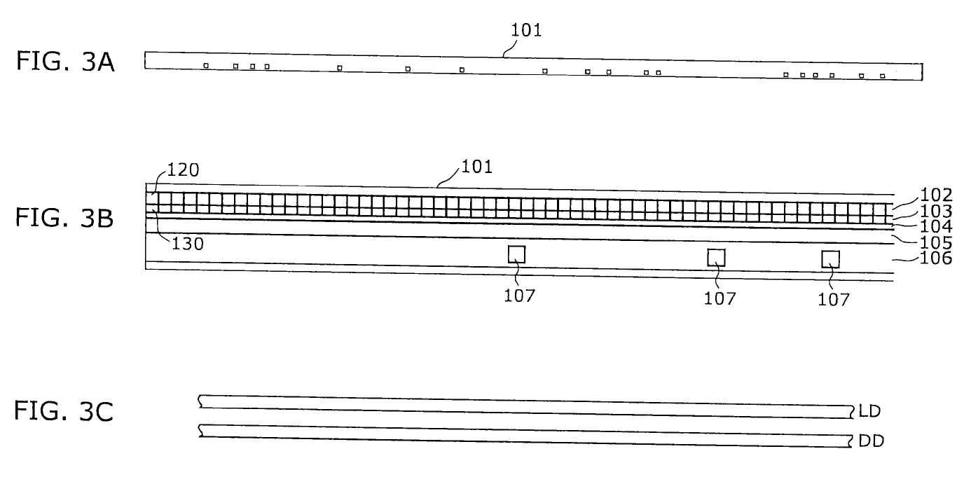

Next, the layout of the semiconductor chip that is an embodiment of the present invention will be described. FIGS. 2A to 2C are plan views of the semiconductor chip 1. The semiconductor chip 1 is obtained by implementing the circuit of the image sensor shown in FIG. 1 on a semiconductor substrate. FIG. 2A is a plan view showing the whole of the semiconductor chip 1, and FIG. 2B is a plan view showing an enlarged end portion thereof. FIG. 2C is a plan view of a pair of signal lines, showing a partially enlarged view of FIG. 2A. As shown in FIG. 2A, this semiconductor chip 1 has the shape of an elongate rectangle (e.g., a rectangle having a shorter side of about 0.35 mm and a longer side of about 18.5 mm). As shown in FIG. 2B showing an enlarged end portion of the semiconductor chip 1, there are disposed, from one shorter side of the rectangle to the other in the longer side direction, the light-sensitive device portion 2 having the light-sensitive devices 20 arranged linearly thereon, each corresponding to one pixel, the read-out circuit cell portion 3 having the read-out circuit cells 30 arranged linearly thereon, each corresponding to one light-sensitive device 20, the conductor portion 4 in which the common signal line LD for a signal output and the common signal line DD for a reference output, which are a pair of signal lines, are formed, the logic circuit portion 5, and the analog circuit portion 6. The analog circuit portion 6 has a plurality of input/output pads 7 provided therein.

The common signal line LD for a signal output and the common signal line DD for a reference output are formed from the vicinity of the left end of the longer side of the conductor portion 4 to the vicinity of the right end thereof. As shown in FIG. 2C, they extend in the longer side direction while exchanging their positions in the shorter side direction every predetermined length. Specifically, the common signal line LD for a signal output is composed of a repeated pattern of a near segment 43 located closer to a practical outer edge of the logic circuit portion 5 extending in the longer side direction, a far segment 41 located farther therefrom, and connecting segments 42 and 44 connecting therebetween. The connecting segments 42 and 44 are inclined in an oblique direction (e.g., 45 degrees) with respect to the longer side direction. Similarly, the common signal line DD for a reference output is composed of a repeated pattern of a near segment 45 located closer to the practical outer edge of the logic circuit portion 5 extending in the longer side direction, a far segment 47 located farther therefrom, and connecting segments 46 and 48 connecting therebetween. The connecting segments 46 and 48 are inclined in an oblique direction (e.g., 45 degrees) with respect to the longer side direction. The common signal line LD for a signal output and the common signal line DD for a reference output are formed in such a way that a near segment of one common signal line is parallel to a far segment of the other, that is, the near segment 45 is parallel to the far segment 41 and the near segment 43 is parallel to the far segment 47, and a connecting segment of one common signal line and a connecting segment of the other cross each other, that is, the connecting segment 42 and the connecting segment 46 cross each other and the connecting segment 44 and the connecting segment 48 cross each other. Note that the far segment 41, the near segment 43, and the connecting segment 44 of the common signal line LD for a signal output, and the near segment 45, the connecting segment 46, and the far segment 47 of the common signal line DD for a reference output are formed in a predetermined metal layer, and the connecting segment 42 of the common signal line LD for a signal output and the connecting segment 48 of the common signal line DD for a reference output are formed in a different metal layer.

The common signal line LD for a signal output and the common signal line DD for a reference output are formed in this way, permitting them to act as follows. The common signal line LD for a signal output and the common signal line DD for a reference output are located near the logic circuit portion 5, and therefore a large parasitic capacitance occurs between them and the devices constituting the logic circuit portion 5 or the conductors led therefrom. Thus, from those devices directly or via the conductors, the common signal line LD for a signal output and the common signal line DD for a reference output easily receive, through the parasitic capacitance, switching noise that is synchronous with the external clock CLK. Here, locally considered, the common signal line LD for a signal output and the common signal line DD for a reference output are affected differently by switching noise. For example, the influence of the switching noise is slightly greater for the near segment 45 of the common signal line DD for a reference output than for the far segment 41 of the common signal line LD for a signal output. However, the influence of the switching noise is slightly smaller for the far segment 47 of the common signal line DD for a reference output than for the near segment 43 of the common signal line LD for a signal output. Thus, as a whole, the common signal line LD for a signal output and the common signal line DD for a reference output are affected almost equally by the switching noise, and therefore the noise waveforms superimposed thereon are substantially the same. Substantially the same noise waveforms superimposed on the common signal line LD for a signal output and on the common signal line DD for a reference output are eliminated by the following subtraction circuit 63.

Note that the far segment 41 and the near segment 43 of the common signal line LD for a signal output and the far segment 47 and the near segment 45 of the common signal line DD for a reference output have the predetermined length in the longer side direction that has been optimized by experiment or simulation. Although the predetermined length does not necessarily need to be made constant, it is preferable that it be made constant to facilitate layout design.

Here, the description specifically deals with a semiconductor chip that is an embodiment of the present invention. It should be understood, however, that application of the present invention is not limited to this particular type of semiconductor chip. Obviously, many modifications and variations of the present invention are possible in light of the above teachings. For example, it is possible to offer enhanced speed by providing a common signal line LD for a signal output and a common signal line DD for a reference output, respectively, for a predetermined number of read-out circuit cells. Moreover, it is needless to say that the MOS transistors can be replaced with bipolar transistors. Furthermore, it is to be understood that the present invention is applicable not only to semiconductor chips used as image sensors but also to any other elongate rectangular semiconductor chips.

### INDUSTRIAL APPLICABILITY

The present invention is applicable to an elongate semiconductor chip having a circuit portion where noise tends to occur, and a pair of signal lines formed along the circuit portion, and is particularly suitable for an image sensor having a plurality of light-sensitive devices.

1. A semiconductor chip having a shape of an elongate rectangle, the semiconductor chip comprising:
a logic circuit portion where switching noise occurs; and
a conductor portion having a pair of signal lines formed therein,
wherein the pair of signal lines each have a near segment located closer to a practical outer edge of the logic circuit portion extending in a longer side direction of the logic circuit portion, a far segment located farther therefrom, and a connecting segment connecting therebetween, and
wherein the pair of signal lines are disposed in such a way that a near segment of one of the pair of signal lines is parallel to a far segment of an other, and a connecting segment of one of the pair of signal lines and a connecting segment of an other cross each other.

2. The semiconductor chip of claim 1, further comprising:
a light-sensitive portion in which a plurality of light-sensitive devices, each corresponding to one pixel, are arranged linearly in a longer side direction; and
a read-out circuit cell portion in which a plurality of read-out circuit cells, each corresponding to one light-sensitive device, are arranged linearly in the longer side direction,
wherein the logic circuit portion generates a control signal for controlling the read-out circuit cell portion, and
wherein the pair of signal lines are composed of a common signal line for a signal output of the plurality of light-sensitive devices and a common signal line for a reference output of the plurality of light-sensitive devices, and are formed between the read-out circuit cell portion and the logic circuit portion.

3. The semiconductor chip of claim 1, further comprising:
an analog circuit portion including a subtraction circuit that receives voltages of the pair of signal lines.

4. The semiconductor chip of claim 1,
wherein the near segment and the far segment have a predetermined and constant length.

5. The semiconductor chip of claim 1,
wherein the connecting segments each have a portion that is inclined in an oblique direction with respect to a longer side direction, of these connecting segments crossing each other, one is formed in a metal layer different from a metal layer in which the near segment and the far segment are formed.

6. The semiconductor chip of claim 2, further comprising:
an analog circuit portion including a subtraction circuit that receives voltages of the pair of signal lines.

7. The semiconductor chip of claim 2,
wherein the near segment and the far segment have a predetermined and constant length.

8. The semiconductor chip of claim 2,
wherein the connecting segments each have a portion that is inclined in an oblique direction with respect to a longer side direction, of these connecting segments crossing each other, one is formed in a metal layer different from a metal layer in which the near segment and the far segment are formed.
